(19) United States
(12) Patent Application Publication
(10) Pub. No.: US 2024/0113144 A1
(43) Pub. Date: Apr. 4, 2024

(54) SOLID-STATE IMAGING DEVICE

(71) Applicant: Sharp Semiconductor Innovation Corporation, Tenri City, Nara (JP)

(72) Inventor: Sota HIDA, Tenri City, Nara (JP)

(21) Appl. No.: 18/231,811

(22) Filed: Aug. 9, 2023

(30) Foreign Application Priority Data
Sep. 30, 2022 (JP) 2022-157327

(51) Int. Cl. H01L 27/146

(52) U.S. Cl. CPC H01L 27/14627

(57) ABSTRACT

A solid-state imaging device includes: a first imaging pixel receiving a first light flux; a phase difference detecting pixel adjacent to the first imaging pixel, and receiving a pupil-divided light flux; a first imaging microlens disposed above the first imaging pixel, and protruding above the phase difference detecting pixel, the first imaging microlens collecting the first light flux onto the first imaging pixel; and a phase difference detecting microlens disposed above the phase difference detecting pixel, occupying an area smaller than an area occupied by the first imaging microlens, and connected to the first imaging microlens, the phase difference detecting microlens collecting the pupil-divided light flux onto the phase difference detecting pixel.

### CROSS-REFERENCE TO RELATED APPLICATIONS

The present disclosure relates to a solid-state imaging device. The present application claims priority from Japanese Patent Application JP2022-157327 filed on Sep. 30, 2022, the content of which is hereby incorporated by reference into this application.

### BACKGROUND

### Technical Field

Japanese Patent Application Publication No. 2014-089432 discloses a solid-state imaging device. In the solid-state imaging device, a first microlens collects light onto an imaging pixel. Furthermore, a second microlens collects light onto a phase difference detecting pixel. A focal length of the second microlens is shorter than a focal length of the first microlens. A focal point of the first microlens is positioned on a light receiving surface of a photodiode. A focal point of the second microlens is away from the light receiving surface, and positioned on a light blocking film (see paragraphs [0020], [0065], and [0066]).

### SUMMARY

As to the solid-state imaging device disclosed in Japanese Patent Application Publication No. 2014-089432, the focal length of the second microlens that collects light onto the phase difference detecting pixel is shorter than the focal length of the first microlens that collects light onto the imaging pixel.

Hence, a radius of curvature of the second microlens could be a half or less of a diagonal dimension of the phase difference detecting pixel. This radius of curvature could create a region, on the phase difference detecting pixel, where the microlens is not disposed. The region where the microlens is not disposed is a cause of noise to be imposed on a phase difference detecting signal to be output from the phase difference detecting pixel. The noise deteriorates phase difference detecting characteristics of the phase difference detecting pixel.

An aspect of the present disclosure is devised in view of the above problems. An aspect of the present disclosure is intended to provide a solid-state imaging device capable of, for example, improving phase difference detecting characteristics of a phase difference detecting pixel.

A solid-state imaging device according to an aspect of the present disclosure includes: a first imaging pixel receiving a first light flux; a phase difference detecting pixel adjacent to the first imaging pixel, and receiving a pupil-divided light flux; a first imaging microlens disposed above the first imaging pixel, and protruding above the phase difference detecting pixel, the first imaging microlens collecting the first light flux onto the first imaging pixel; and a phase difference detecting microlens disposed above the phase difference detecting pixel, occupying an area smaller than an area occupied by the first imaging microlens, and connected to the first imaging microlens, the phase difference detecting microlens collecting the pupil-divided light flux onto the phase difference detecting pixel.

### BRIEF DESCRIPTION OF DRAWINGS

FIG. 1 is a top view schematically illustrating a solid-state imaging device of a first embodiment;

FIG. 2 is a cross-sectional view schematically illustrating a cross-section, of the solid-state imaging device of the first embodiment, taken along line a-a′ in FIG. 1;

FIG. 3 is a cross-sectional view schematically illustrating a cross-section, of the solid-state imaging device of the first embodiment, taken along line b-b′ in FIG. 1;

FIG. 4 is a cross-sectional view schematically illustrating a periphery of a left-eye pixel included in the solid-state imaging device of the first embodiment;

FIG. 5 is a cross-sectional view schematically illustrating a periphery of a right-eye pixel included in the solid-state imaging device of the first embodiment;

FIG. 6 is a graph showing an ideal phase difference detecting characteristic;

FIG. 7 is a graph showing a result of simulating a phase difference detecting characteristic of the solid-state imaging device of the first embodiment;

FIG. 8 is a cross-sectional view schematically illustrating how light is incident on the solid-state imaging device of the first embodiment;

FIG. 9 is a top view schematically illustrating a solid-state imaging device of a first reference example;

FIG. 10 is a cross-sectional view schematically illustrating a cross-section, of the solid-state imaging device of the first reference example, taken along line a-a′ in FIG. 9;

FIG. 11 is a cross-sectional view schematically illustrating a cross-section, of the solid-state imaging device of the first reference example, taken along line b-b′ in FIG. 9;

FIG. 12 is a top view schematically illustrating a solid-state imaging device of a second reference example;

FIG. 13 is a cross-sectional view schematically illustrating a cross-section, of the solid-state imaging device of the second reference example, taken along line a-a′ in FIG. 12;

FIG. 14 is a cross-sectional view schematically illustrating a cross-section, of the solid-state imaging device of the second reference example, taken along line b-b′ in FIG. 12;

FIG. 15 is a cross-sectional view schematically illustrating how light is incident on the solid-state imaging device of the second reference example; and

FIG. 16 is a graph showing a result of simulating a phase difference detecting characteristic of the solid-state imaging device of the second reference example.

### DESCRIPTION OF EMBODIMENTS

An embodiment of the present disclosure will be described below, with reference to the drawings. Note that, throughout the drawings, like reference signs denote identical or similar constituent features. Such features will not be repeatedly elaborated upon.

### 1. First Embodiment

1.1 Solid-State Imaging Device

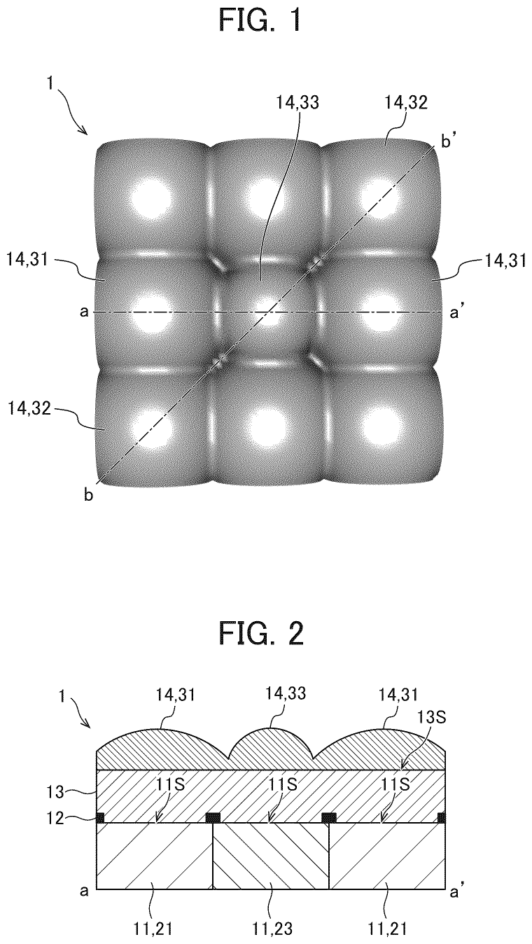

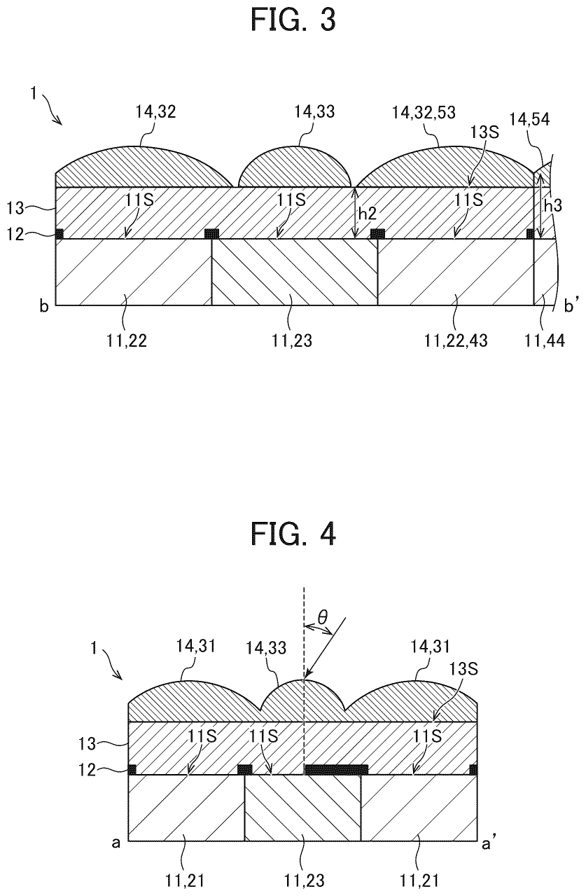

FIG. 1 is a top view schematically illustrating a solid-state imaging device of a first embodiment. FIG. 2 is a cross-sectional view schematically illustrating a cross-section, of the solid-state imaging device of the first embodiment, taken along line a-a′ in FIG. 1. FIG. 3 is a cross-sectional view schematically illustrating a cross-section, of the solid-state imaging device of the first embodiment, taken along line b-b′ in FIG. 1. The line a-a′ extends in an opposite side direction of the solid-state imaging device. Hence, FIG. 2 is a cross-sectional view in the opposite side direction. The line b-b′ is a line extending in an opposite angle direction of the solid-state imaging device. Hence, FIG. 3 is a cross-sectional view in the opposite angle direction.

A solid-state imaging device 1 of the first embodiment illustrated in FIGS. 1, 2, and 3 obtains an image of an object, and outputs an imaging signal based on the image of the object. Furthermore, the solid-state imaging device 1 detects a phase difference, and outputs a phase difference detecting signal based on a defocus direction and a defocus amount. The phase difference detecting signal to be output is used for image plane phase-difference autofocusing.

As illustrated in FIGS. 1, 2 and 3, the solid-state imaging device 1 includes a plurality of pixels 11, a light blocking film 12, a planarization film 13, and a plurality of microlenses 14.

Each of the pixels 11 has a square planar shape. The plurality of pixels 11 are arranged in a matrix. The plurality of pixels 11 are arranged in a light receiving region to receive light that forms an object image. Each of the pixels 11 has a light receiving surface 11S. Each pixel 11 photoelectrically converts the light received on the light receiving surface 11S, and outputs an electric signal. Thus, each pixel 11 outputs an electric signal based on intensity of the light received on the light receiving surface 11S.

The light blocking film 12 has a lattice shape. The light blocking film 12 covers a vicinity of a boundary between the light receiving surfaces 11S of the adjacent pixels 11. The light blocking film 12 blocks light that forms the object image. Thus, the light blocking film 12 keeps the light, which forms the object image, from the vicinity of the boundary.

The planarization film 13 is disposed on the light receiving surfaces 11S of the plurality of pixels 11, and overlaps the light blocking film 12. The planarization film 13 fills the irregularities formed by the light blocking film 12, and provides a flat surface 13S. The planarization film 13 transmits the light that forms the object image.

The plurality of microlenses 14 are arranged on the flat surface 13S. Each of the plurality of microlenses 14 is disposed across the planarization film 13 above a respective one of the plurality of pixels 11. Each microlens 14 disposed above the respective pixel 11 collects light onto the light receiving surface 11S of the pixel 11.

1.2 Imaging Pixel, Phase Difference Detecting Pixel, Imaging Microlens, and Phase Difference Detecting Microlens

The plurality of pixels 11 include a first imaging pixel 21, a second imaging pixel 22, and a phase difference detecting pixel 23.

The first imaging pixel 21, the second imaging pixel 22, and the phase difference detecting pixel 23 are arranged in the same light receiving region. The first imaging pixel 21 is adjacent to the phase difference detecting pixel 23 in the opposite side direction of the phase difference detecting pixel 23. The second imaging pixel 22 is adjacent to the phase difference detecting pixel 23 in the opposite angle direction of the phase difference detecting pixel 23.

The plurality of microlenses 14 include a first imaging microlens 31, a second imaging microlens 32, and a phase difference detecting microlens 33.

The first imaging microlens 31, which corresponds to the first imaging pixel 21, is disposed above the first imaging pixel 21. The second imaging microlens 32, which corresponds to the second imaging pixel 22, is disposed above the second imaging pixel 22. The phase difference detecting microlens 33, which corresponds to the phase difference detecting pixel 23, is disposed above the phase difference detecting pixel 23.

The first imaging microlens 31 collects a first light flux onto the first imaging pixel 21. The first imaging pixel 21 receives the collected first light flux, and outputs an electric signal based on the received first light flux. The first light flux is received on the light receiving surface 11S of the first imaging pixel 21. The electric signal output from the first imaging pixel 21 is an imaging signal. The second imaging microlens 32 collects a second light flux onto the second imaging pixel 22. The second imaging pixel 22 receives the collected second light flux, and outputs an electric signal based on the received second light flux. The second light flux is received on the light receiving surface 11S of the second imaging pixel 22. The electric signal output from the second imaging pixel 22 is an imaging signal. The phase difference detecting microlens 33 collects a light flux subjected to pupil division (hereinafter referred to as “a pupil-divided light flux”) onto the phase difference detecting pixel 23. The phase difference detecting pixel 23 receives the collected pupil-divided light flux, and outputs an electric signal based on the received pupil-divided light flux. The collected pupil-divided light flux is received on the light receiving surface 11S of the phase difference detecting pixel 23. The electric signal output from the phase difference detecting pixel 23 is a phase difference detecting signal.

The plurality of pixels 11 and the plurality of microlenses 14 may be shaped and arranged in a different manner from the shapes and the arrangement illustrated in FIGS. 1, 2, and 3.

1.3 Curvature of Each Microlens

In the description below, a curvature of each microlens 14 is a curvature of an incidence plane of the microlens 14 in the cross-section including an optical axis of the microlens 14.

Each microlens 14 is rotationally symmetrical when the optical axis of the microlens 14 is given as a rotationally symmetrical axis. Hence, in the cross-section including the optical axis of each microlens 14, the curvature of the microlens 14 is constant regardless of the direction of the cross-section. Therefore, the curvature of each microlens 14 is constant regardless of whether the cross-sectional direction is in any circumferential direction. Such a feature allows each microlens 14 to collect light as much as possible.

1.4 Optimizing Imaging Microlens and Phase Difference Detecting Microlens

In the description below, an incident angle θ of light incident on each pixel 11 is an angle formed between an incident direction of the incident light and a line normal to the light receiving surface 11S of the pixel 11.

What is required for the first imaging pixel 21 and the second imaging pixel 22 is different from what is required for the phase difference detecting pixel 23. Hence, the optimization of the first imaging microlens 31 and the second imaging microlens 32 is different from the optimization of the phase difference detecting microlens 33.

The first imaging pixel 21 and the second imaging pixel 22 are required to have high sensitivity and excellent oblique-incidence characteristics. Hence, the first imaging microlens 31 and the second imaging microlens 32 are optimized to provide the first imaging pixel 21 and the second imaging pixel 22 with high sensitivity and excellent oblique-incidence characteristics. If the first imaging pixel 21 and the second imaging pixel 22 have excellent oblique-incidence characteristics, it means that the incident angle θ is wide while the first imaging pixel 21 and the second imaging pixel 22 have stable sensitivity.

Hence, each of the first imaging microlens 31 and the second imaging microlens 32 has a focal point in a photoelectric conversion region located behind the light receiving surface 11S of a respective one of the first imaging pixel 21 and the second imaging pixel 22. This feature is devised because of the reasons below.

If the distance is long from the first imaging microlens 31 to the light receiving surface 11S of the first imaging pixel 21, the first imaging pixel 21 exhibits a poor oblique-incidence characteristic. This is because a position for receiving the incident light having the incident angle θ larger than 0° shifts from the light receiving surface 11S of the first imaging pixel 21 toward the light receiving surface 11S of a pixel 11 adjacent to the first imaging pixel 21. As a result, the incident light is highly likely not to be incident on the light receiving surface 11S of the first imaging pixel 21. For example, if refraction in the first imaging microlens 31 is ignored, when the distance is increased from 1 μm to 2 μm, the position for receiving the incident light having an incident angle θ of 30° shifts by approximately 0.6 μm from the light receiving surface 11S of the first imaging pixel 21 toward the light receiving surface 11S of the pixel 11 adjacent to the first imaging pixel 21. Accordingly, the incident light is highly likely not to be incident on the light receiving surface 11S of the first imaging pixel 21. This is also true when the distance from the second imaging microlens 32 to the light receiving surface 11S of the second imaging pixel 22 increases. However, each of the first imaging microlens 31 and the second imaging microlens 32 has the focal point behind the light receiving surface 11S of a respective one of the first imaging pixel 21 and the second imaging pixel 22. Thanks to such a feature, each of the first imaging microlens 31 and the second imaging microlens 32 can be positioned closer to the light receiving surface 11S of a respective one of the first imaging pixel 21 and the second imaging pixel 22. Thanks to such features, the incident light collected by the first imaging microlens 31 and the second imaging microlens 32 can be fully received on the light receiving surface 11S of a respective one of the first imaging pixel 21 and the second imaging pixel 22. Note that neither the first imaging microlens 31 nor the second imaging microlens 32 has a focal point on the light receiving surface 11S of the first imaging pixel 21 or the second imaging pixel 22, which does not cause any particular problem.

On the other hand, the phase difference detecting pixel 23 is required to have an excellent phase difference detecting characteristic. Hence, the phase difference detecting microlens 33 is optimized to provide the phase difference detecting pixel 23 with an excellent phase difference detecting characteristic. If the phase difference detecting pixel 23 has an excellent phase difference detecting characteristic, it means that the phase difference detecting pixel 23 exhibits a significant change in sensitivity when the incident angle θ changes more than a specific angle. The particular angle of incidence is, for example, 0°.

Hence, the phase difference detecting microlens 33 has a focal point on the light receiving surface 11S of the phase difference detecting pixel 23. The phase difference detecting microlens 33 has a focal point on the light receiving surface 11S of the phase difference detecting pixel 23 on both of: a cross-section including the optical axis of the phase difference detecting microlens 33 and laid in parallel with the opposite side direction of the phase difference detecting pixel 23 illustrated in FIG. 2; and a cross-section including the optical axis of the phase difference detecting microlens 33 and laid in parallel with the opposite angle direction of the phase difference detecting pixel 23 illustrated in FIG. 3.

The distance from the phase difference detecting microlens 33 to the light receiving surface 11S of the phase difference detecting pixel 23 is the same as the distance from the first imaging microlens 31 to the light receiving surface 11S of the first imaging pixel 21 and the distance from the second imaging microlens 32 to the light receiving surface 11S of the second imaging pixel 22. Then, the phase difference detecting microlens 33 has a focal point on the light receiving surface 11S of the phase difference detecting pixel 23. Furthermore, each of the first imaging microlens 31 and the second imaging microlens 32 has a focal point behind the light receiving surface 11S of a respective one of the first imaging pixel 21 and the second imaging pixel 22. Thanks to such a feature, the phase difference detecting microlens 33 has a focal length shorter than a focal length of each of the first imaging microlens 31 and the second imaging microlens 32.

1.5 Reducing Gap Between Imaging Microlens and Phase Difference Detecting Microlens

In order to make the focal length of the phase difference detecting microlens 33 shorter than the focal length of each of the first imaging microlens 31 and the second imaging microlens 32, the curvature of the phase difference detecting microlens 33 is made preferably smaller than the curvature of each of the first imaging microlens 31 and the second imaging microlens 32. If the curvature of the phase difference detecting microlens 33 is smaller than the curvature of each of the first imaging microlens 31 and the second imaging microlens 32, a diameter of the phase difference detecting microlens 33 is smaller in plan view than: the opposite side dimension and the opposite angle dimension of the phase difference detecting pixel 23; and a diameter of each of the first imaging microlens 31 and the second imaging microlens 32. Hence, in plan view, an area occupied by the phase difference detecting microlens 33 is smaller than: an area occupied by the phase difference detecting pixel 23; and an area occupied by each of the first imaging microlens 31 and the second imaging microlens 32. Thus, created above an outer peripheral portion of the phase difference detecting pixel 23 is a region in which the phase difference detecting microlens 33 is not disposed.

In the created region, an outer peripheral portion of each of the first imaging microlens 31 and the second imaging microlens 32 is disposed. Hence, in plan view, the first imaging microlens 31 is disposed above the first imaging pixel 21, and protrudes above the outer peripheral portion of the phase difference detecting pixel 23. Furthermore, in plan view, the second imaging microlens 32 is disposed above the second imaging pixel 22, and protrudes above the outer peripheral portion of the phase difference detecting pixel 23. Such a feature can reduce formation of a void region in which no microlens is disposed in the region above the phase difference detecting pixel 23. Moreover, the feature allows the first imaging microlens 31 and the second imaging microlens 32 to collect light, incident on the region above the outer peripheral portion of the phase difference detecting pixel 23, respectively onto the first imaging pixel 21 and the second imaging pixel 22.

In addition, in a plan view, the first imaging microlens 31 is connected to the phase difference detecting microlens 33. Such a feature can further reduce formation of a void region between the first imaging microlens 31 and the phase difference detecting microlens 33. In the void region, no microlens is disposed in the region above the phase difference detecting pixel 23. Furthermore, the feature allows the first imaging microlens 31 to more efficiently collect light, incident on the region above the outer peripheral portion of the phase difference detecting pixel 23, onto the first imaging pixel 21.

Hence, in the solid-state imaging device 1, the first imaging microlens 31 and the second imaging microlens 32 are different in radius of curvature from the phase difference detecting microlens 33. Moreover, the first imaging microlens 31 and the second imaging microlens 32 are different in planar shape from the phase difference detecting microlens 33. Such features can reduce formation of a gap between the first imaging microlens 31 and the phase difference detecting microlens 33, and between the second imaging microlens 32 and the phase difference detecting microlens 33. These features can improve a phase difference detecting characteristic of the phase difference detecting pixel 23.

In addition, in the solid-state imaging device 1, the first imaging microlens 31 and the second imaging microlens 32 are the same in height as the phase difference detecting microlens 33. Such a feature can reduce effect caused to a process to be carried out after the plurality of microlenses 14 are formed.

1.6 Boundary Between Adjacent Microlenses

As illustrated in FIG. 3, the solid-state imaging device 1 includes two imaging pixels 43 and 44 adjacent to each other in the opposite angle direction of the phase difference detecting pixel 23. Furthermore, the solid-state imaging device 1 includes two imaging microlenses 53 and 54 arranged respectively above the two imaging pixels 43 and 44. The two imaging pixels 43 and 44 may include the first imaging pixel 21 or the second imaging pixel 22. The two imaging microlenses 53 and 54 may include the first imaging microlens 31 or the second imaging microlens 32.

The two imaging microlenses 53 and 54 respectively correct a third light flux and a fourth light flux onto the two imaging pixels 43 and 44. The two imaging pixels 43 and 44 respectively receive the collected third and fourth light fluxes.

When the phase difference detecting microlens 33 is small in diameter, a height h2, of the phase difference detecting microlens 33 and the second imaging microlens 32, at a boundary between the phase difference detecting microlens 33 and the second imaging microlens 32 is lower than a height h3, of the two imaging microlenses 53 and 54, at a boundary between the two imaging microlenses 53 and 54. Here, the height h2 is a distance from the light receiving surface 11S of each of the phase difference detecting pixel 23 and the second imaging pixel 22 to the incidence plane of a respective one of the phase difference detecting microlens 33 and the second imaging microlens 32. Furthermore, the height h3 is a distance from the light receiving surface 11S of each of the two imaging pixels 43 and 44 to the incidence plane of a respective one of the two imaging microlenses 53 and 54.

1.7 Pupil Division

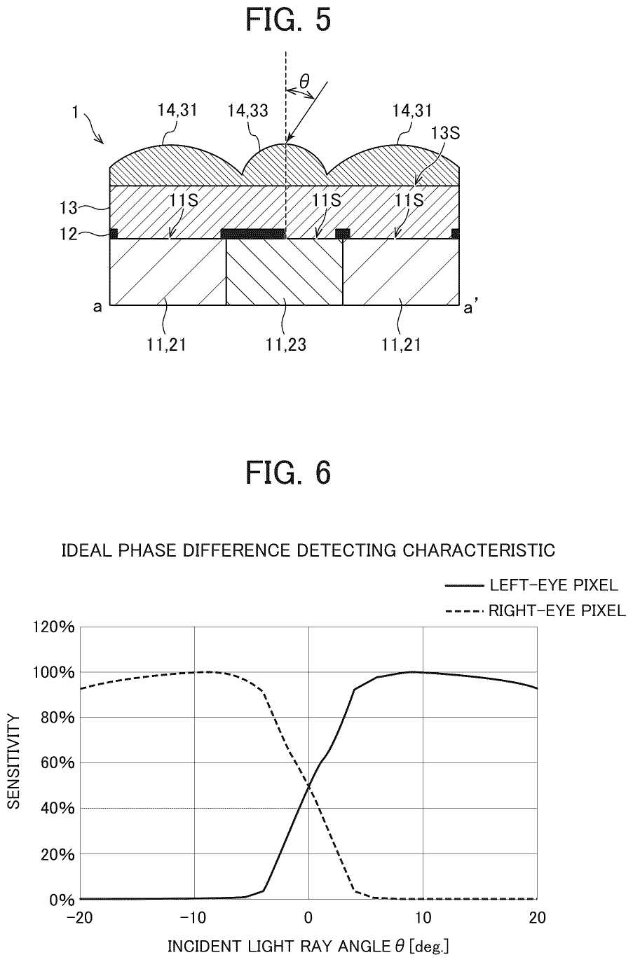

FIG. 4 is a cross-sectional view schematically illustrating a periphery of a left-eye pixel included in the solid-state imaging device of the first embodiment. FIG. 5 is a cross-sectional view schematically illustrating a periphery of a right-eye pixel included in the solid-state imaging device of the first embodiment.

In order to allow the phase difference detecting pixel 23 to receive a pupil-divided light flux, the light blocking film 12 is used to partially block, from the light, the light receiving surface 11S of the phase difference detecting pixel 23. With this technique, as illustrated in FIG. 4, the right side of the light receiving surface 11S of the phase difference detecting pixel 23 is blocked by the light blocking film 12, and the left side of the light receiving surface 11S of the phase difference detecting pixel 23 is enabled. In such a case, the phase difference detecting pixel 23 functions as the left-eye pixel. On the other hand, as illustrated in FIG. 5, the left side of the light receiving surface 11S of the phase difference detecting pixel 23 is blocked by the light blocking film 12, and the right side of the light receiving surface 11S of the phase difference detecting pixel 23 is enabled. In such a case, the phase difference detecting pixel 23 functions as the right-eye pixel.

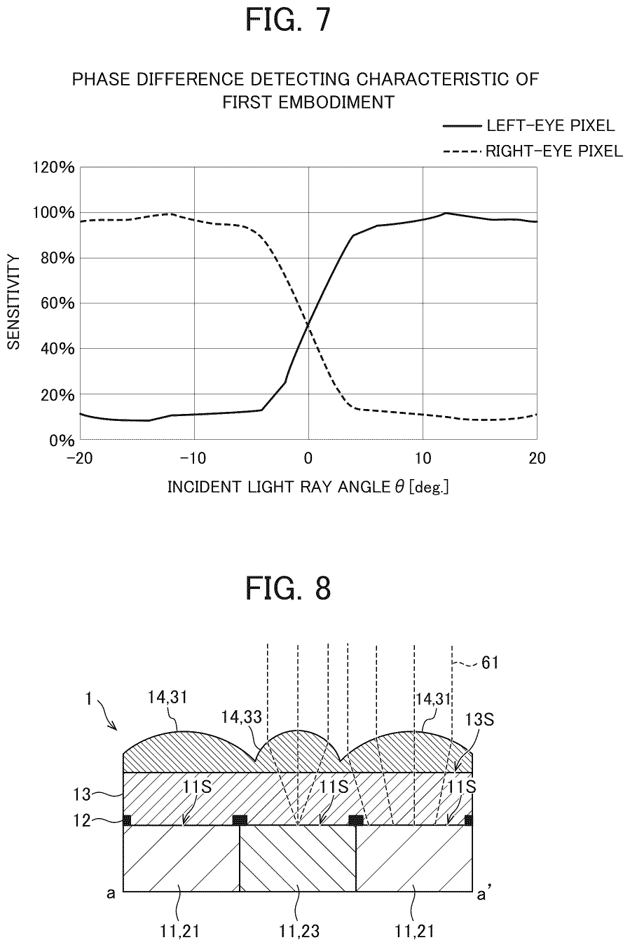

FIG. 6 is a graph showing an ideal phase difference detecting characteristic. FIG. 7 is a graph showing a result of simulating a phase difference detecting characteristic of the solid-state imaging device of the first embodiment. As to the graph, the horizontal axis represents an incident angle θ of a light ray (an incident light ray angle θ) on each of the left-eye pixel and the right-eye pixel, and the vertical axis represents a sensitivity of each pixel. The sensitivity is normalized so that the maximum value is 100%. FIG. 8 is a cross-sectional view schematically illustrating how light is incident on the solid-state imaging device of the first embodiment.

As illustrated in FIG. 6, the ideal phase difference detecting characteristic shows that a rate of the sensitivity of the right-eye pixel to the sensitivity of the left-eye pixel is high in an incident angle range in which the incident light ray angle θ is smaller than 0°, and that a rate of the sensitivity of the left-eye pixel to the sensitivity of the right-eye pixel is high in an incident angle range in which the incident light ray angle θ is larger than 0°. In order to obtain a desirable phase difference detecting characteristic, the sensitivity of the left-eye pixel is expected to reach 0% in the former range, and the sensitivity of the right-eye pixel is expected to reach 0% in the latter range.

As illustrated in FIG. 7, the solid-state imaging device 1 has a phase difference detecting characteristic close to the ideal phase difference detecting characteristic illustrated in FIG. 6. The solid-state imaging device 1 has such a phase difference detecting characteristic because, as illustrated in FIG. 8, the solid-state imaging device 1 can: reduce formation of a gap between the first imaging microlens 31 and the phase difference detecting pixel 23 and between the second imaging microlens 32 and the phase difference detecting pixel 23; and keep incident light 61 from entering the phase difference detecting pixel 23 through the formed gap. Such features become more definite in comparison between a second reference example and the first embodiment to be described below.

1.8 Comparison Between Reference Examples and First Embodiment

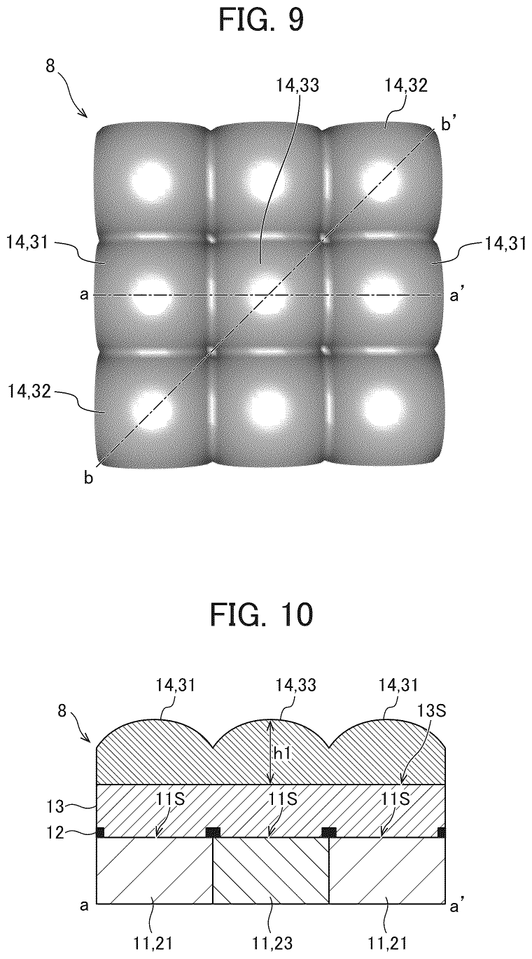

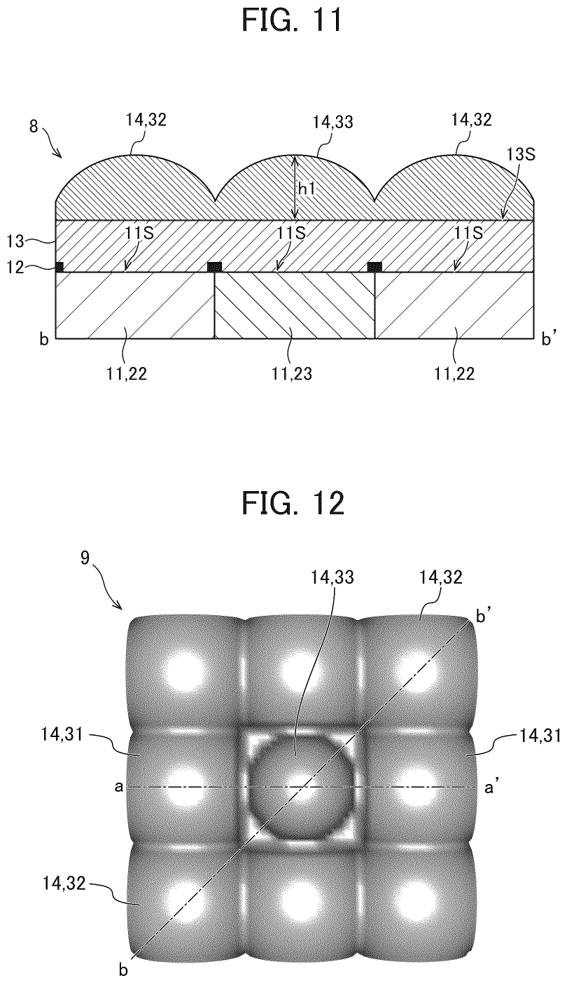

FIG. 9 is a top view schematically illustrating a solid-state imaging device of a first reference example. FIG. 10 is a cross-sectional view schematically illustrating a cross-section, of the solid-state imaging device of the first reference example, taken along line a-a′ in FIG. 9. FIG. 11 is a cross-sectional view schematically illustrating a cross-section, of the solid-state imaging device of the first reference example, taken along line b-b′ in FIG. 9.

FIGS. 9, 10, and 11 illustrate a solid-state imaging device 8 of the first reference example. In the solid-state imaging device 8, the first imaging microlens 31 and the second imaging microlens 32 are the same in height; namely a height h1, and in shape, as the phase difference detecting microlens 33. Hence, as to the solid-state imaging device 8, optimization cannot be provided independently for the first and second imaging pixels 21 and 22 and for the phase difference detecting pixel 23. Therefore, it is impossible to simultaneously satisfy both a requirement for the first and second imaging pixels 21 and 22 and a requirement for the phase difference detecting pixel 23.

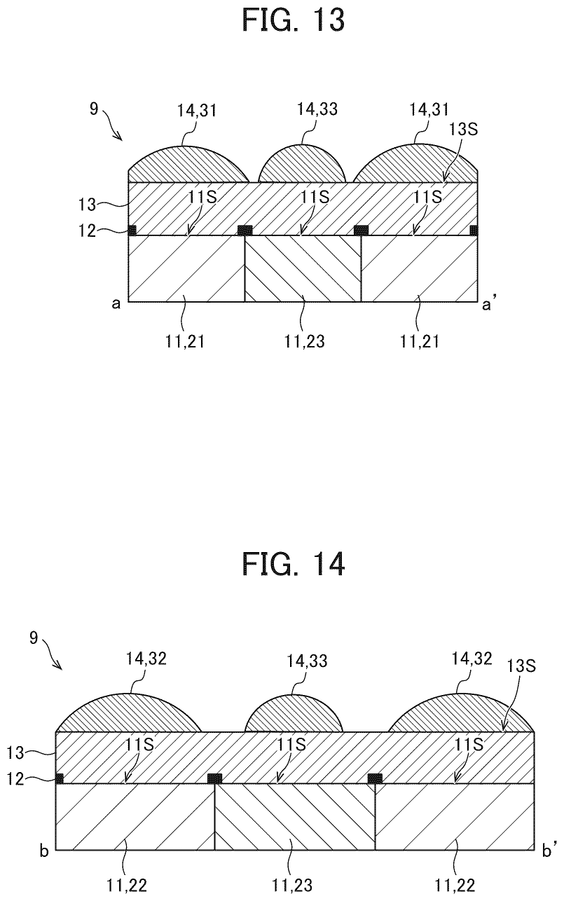

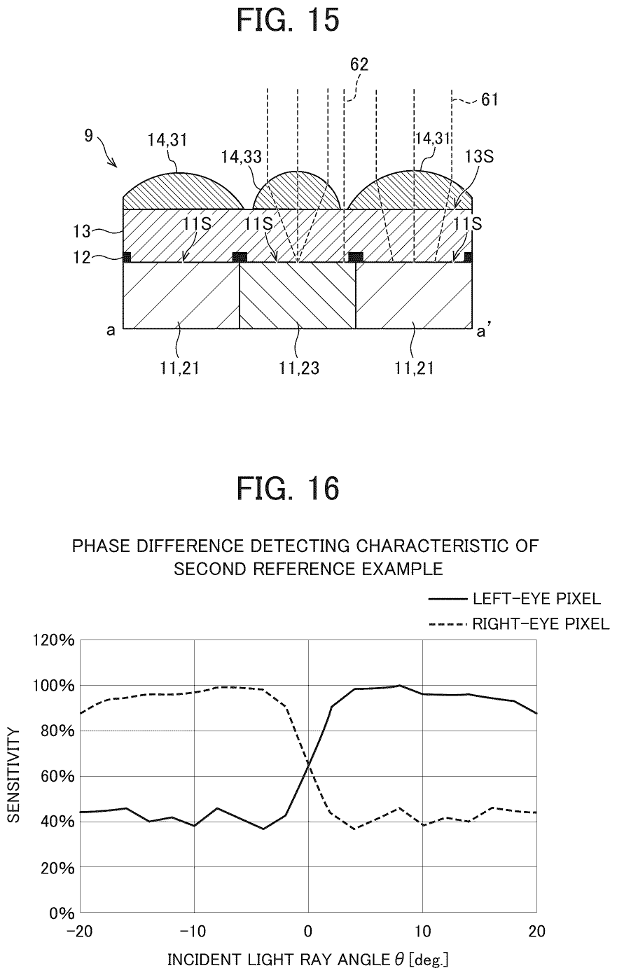

FIG. 12 is a top view schematically illustrating a solid-state imaging device of the second reference example. FIG. 13 is a cross-sectional view schematically illustrating a cross-section, of the solid-state imaging device of the second reference example, taken along line a-a′ in FIG. 12. FIG. 14 is a cross-sectional view schematically illustrating a cross-section, of the solid-state imaging device of the second reference example, taken along line b-b′ in FIG. 12. FIG. 15 is a cross-sectional view schematically illustrating how light is incident on the solid-state imaging device of the second reference example.

FIGS. 12, 13, and 14 illustrate a solid-state imaging device 9 of the second reference example. In the solid-state imaging device 9, the first imaging microlens 31 and the second imaging microlens 32 are different in shape from the phase difference detecting microlens 33. Hence, as to the solid-state imaging device 9, optimization can be provided independently for the first and second imaging pixels 21 and 22 and for the phase difference detecting pixel 23. Therefore, it is possible to simultaneously satisfy both a requirement for the first and second imaging pixels 21 and 22 and a requirement for the phase difference detecting pixel 23.

However, as to the solid-state imaging device 9 of the second reference example, the first imaging microlens 31 and the second imaging microlens 32 are arranged respectively only above the first imaging pixel 21 and the second imaging pixel 22. Hence, a large gap is formed between the first imaging microlens 31 and the phase difference detecting microlens 33, and between the second imaging microlens 32 and the phase difference detecting microlens 33. Thus, as illustrated in FIG. 15, a portion 62 of the incident light 61 enters the phase difference detecting pixel 23 through the formed large gap. Therefore, the portion 62 of the incident light 61 is a cause of noise to be imposed on a phase difference detecting signal. The noise keeps: the sensitivity of the left-eye pixel from reaching 0% in the incident angle range in which the incident light ray angle θ is smaller than 0°; and the sensitivity of the right-eye pixel from reaching 0% in the incident angle range in which the incident light ray angle θ is larger than 0°.

FIG. 16 is a graph showing a result of simulating a phase difference detecting characteristic of the solid-state imaging device of the second reference example. As to the graph, the horizontal axis represents an incident angle θ of a light ray (an incident light ray angle θ) on each of the left-eye pixel and the right-eye pixel, and the vertical axis represents a sensitivity of each pixel. The sensitivity is normalized so that the maximum value is 100%.

FIG. 16 shows that, as to the solid-state imaging device 9 of the second reference example, the sensitivity of the left-eye pixel rises to approximately 40% in the incident angle range in which the incident light ray angle θ is smaller than 0°, and the sensitivity of the right-eye pixel rises to approximately 40% in the incident angle range in which the incident light ray angle θ is larger than 0°. Hence, the solid-state imaging device 9 does not have a phase difference detecting characteristic close to the ideal phase difference detecting characteristic illustrated in FIG. 6. The solid-state imaging device 9 does not have such a phase difference detecting characteristic. This is because a large gap is formed between the first imaging microlens 31 and the phase difference detecting microlens 33 and between the second imaging microlens 32 and the phase difference detecting microlens 33, such that the portion 62 of the incident light 61 enters the phase difference detecting pixel 23 through the formed large gap.

In contrast, FIG. 7 shows that, as to the solid-state imaging device 1 of the first embodiment, the sensitivity of the left-eye pixel falls to approximately 10% in the incident angle range in which the incident light ray angle θ is smaller than 0°, and the sensitivity of the right-eye pixel falls to approximately 10% in the incident angle range in which the incident light ray angle θ is larger than 0°. Hence, the solid-state imaging device 1 of the first embodiment has a phase difference detecting characteristic close to the ideal phase difference detecting characteristic illustrated in FIG. 6. The solid-state imaging device 1 has such a phase difference detecting characteristic. This is because the solid-state imaging device 1 reduces formation of a gap between the first imaging microlens 31 and the phase difference detecting microlens 33 and between the second imaging microlens 32 and the phase difference detecting microlens 33, and keeps the incident light 61 from entering the phase difference detecting pixel 23 through the formed gap.

The present disclosure is not limited to the above-described embodiment, and may be replaced with a configuration substantially the same as, a configuration having the same advantageous effects as, or a configuration capable of achieving the same object as the configurations described in the above-described embodiment.

1. A solid-state imaging device, comprising:
a first imaging pixel configured to receive a first light flux;
a phase difference detecting pixel adjacent to the first imaging pixel, and configured to receive a pupil-divided light flux;
a first imaging microlens disposed above the first imaging pixel, and protruding above the phase difference detecting pixel, the first imaging microlens being configured to collect the first light flux onto the first imaging pixel; and
a phase difference detecting microlens disposed above the phase difference detecting pixel, occupying an area smaller than an area occupied by the first imaging microlens, and connected to the first imaging microlens, the phase difference detecting microlens being configured to collect the pupil-divided light flux onto the phase difference detecting pixel.

2. The solid-state imaging device according to claim 1,
wherein the phase difference detecting microlens has a focal length shorter than a focal length of the first imaging microlens.

3. The solid-state imaging device according to claim 1,
wherein, in a cross-section including an optical axis of the phase difference detecting microlens, a curvature of an incidence plane of the phase difference detecting microlens is constant regardless of a direction of the cross-section.

4. The solid-state imaging device according to claim 1, further comprising:
a second imaging pixel adjacent to the phase difference detecting pixel in an opposite angle direction of the phase difference detecting pixel, the second imaging pixel being configured to receive a second light flux;
a second imaging microlens configured to collect the second light flux onto the second imaging pixel;
two imaging pixels adjacent to each other in the opposite angle direction, and each configured to receive one of a third light flux or a fourth light flux; and
two imaging microlenses each disposed above a respective one of the two imaging pixels, and each configured to collect one of the third light flux or the fourth light flux onto a respective one of the two imaging pixels,
wherein a height, of the phase difference detecting microlens and the second imaging microlens, at a boundary between the phase difference detecting microlens and the second imaging microlens is lower than a height, of the two imaging microlenses, at a boundary between the two imaging microlenses.

5. The solid-state imaging device according to claim 1,
wherein the phase difference detecting pixel has a light receiving surface that receives the pupil-divided light flux, and
the phase difference detecting microlens has a focal point on the light receiving surface.

6. The solid-state imaging device according to claim 5,
wherein the phase difference detecting microlens has the focal point on the light receiving surface on both of a cross-section including an optical axis of the phase difference detecting microlens and laid in parallel with an opposite side direction of the phase difference detecting pixel; and a cross-section including the optical axis and laid in parallel with an opposite angle direction of the phase difference detecting pixel.

7. The solid-state imaging device according to claim 1,
wherein the first imaging pixel has a light receiving surface that receives the first light flux, and
the first imaging microlens has a focal point behind the light receiving surface that receives the first light flux.
